(19) United States
(12) Patent Application Publication
(10) Pub. No.: US 2010/0007347 A1
(43) Pub. Date: Jan. 14, 2010

(54) SPLIT GRADIENT COIL FOR MRI

(75) Inventors: Cornelis Leonardus Gerardus Ham, Eindhoven (NL); Gerardus Nerius Peeren, Eindhoven (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/447,001

(22) PCT Filed: Nov. 2, 2007
(86) PCT No.: PCT/IB07/54450

§ 371 Date: Apr. 24, 2009

(30) Foreign Application Priority Data
Nov. 3, 2006 (EP) 06123450.6

(51) Int. Cl. G01R 33/44

(52) U.S. Cl. 324/318

(57) ABSTRACT

An MR system comprising an improved gradient coil that does not compromise patient comfort is disclosed herein. The MR system is either a bore-type or a gap-type system and comprises a main magnet (102, 502) arranged to generate a main magnetic field; an examination region (118, 518) having a central axis (114)—in a bore-type system—or a central plane (514)—in a gap-type system—that is either parallel (for a bore-type MR system) or perpendicular (for a gap-type MR system) to the direction of the main magnetic field; and a gradient coil for generating a magnetic field gradient across the examination region, wherein the gradient coil comprises a first coil portion (108a, 508a) and a second coil portion (108b, 508b) located at different distances from the central axis (in a bore-type system) or from the central plane (in a gap-type system).

### FIELD OF THE INVENTION

This invention relates to a magnetic resonance (MR) system, and particularly to magnetic field gradient coils used in an MR system.

### BACKGROUND OF THE INVENTION

The United States patent application U.S. Pat. No. 5,623,208A discusses a z-axis magnetic field gradient coil structure for producing a desired magnetic field gradient in an MR system. The coil structure comprises a flexible insulating substrate wound on a cylindrical bobbin, with a coil pattern formed on the insulating substrate by etching techniques.

### SUMMARY OF THE INVENTION

One way of increasing the efficiency of operation of the gradient coil is to reduce the diameter of the bobbin; however, that would also reduce patient comfort. It is therefore desirable to have an MR system comprising a more efficient gradient coil that does not compromise patient comfort while the patient is inside the MR system.

Accordingly, an MR system comprising a more efficient gradient coil but which does not compromise patient comfort is disclosed herein.

In one embodiment, the MR system is a bore-type MR system that comprises a main magnet, including a bore, arranged to generate a main magnetic field along the bore; an examination region comprised in the bore and having a central axis parallel to the direction of the main magnetic field; and a primary gradient coil for generating a magnetic field gradient across the examination region, wherein the primary gradient coil comprises a first coil portion and a second coil portion located at different distances from the central axis.

In another embodiment, the MR system is a gap-type MR system that comprises a main magnet, including multiple pole faces separated by a gap, arranged to generate a main magnetic field in the gap; an examination region comprised in the gap and having a central plane perpendicular to the direction of the main magnetic field; and a primary gradient coil for generating a magnetic field gradient across the examination region, wherein the primary gradient coil comprises a first coil portion and a second coil portion located at different distances from the central plane.

In a typical MR system, the three gradient axes (normally designated x, y and z) intersect at a point that may be called the origin of the gradient coordinate system. In most MR system designs, the origin of the gradient coordinate system is configured to coincide with the origin of the MR system and also forms the origin of the central axis of the MR system. The central axis in a bore-type system may be defined as an axis that passes through the origin of the gradient coordinate system and is parallel to the direction of the main magnetic field, while in a gap-type MR system, the central axis is a line that passes through the origin of the gradient coordinate system but is orthogonal to the direction of the main magnetic field. The central plane in a gap-type MR system is defined as a plane that contains the central axis of the gap-type system and is perpendicular to the direction of the main magnetic field.

In some designs of MR systems, the gradient coils have a low current density for portions of the gradient coils that are near the origin of the gradient coordinate system, and higher current densities for portions of the gradient coils that are farther away from the origin along the central axis. The areas with higher current densities contribute more to the stored field energy of the gradient coil, which results in a decreased efficiency of the gradient coil. The distance of a gradient coil from the central axis has a strong influence on the stored field energy, with a smaller distance resulting in a decreased stored field energy, and therefore increased efficiency of operation. Therefore, it is possible to decrease the stored field energy of a part of the gradient coil, and thereby increase its efficiency, by moving that part of the gradient coil inwards (i.e., towards the central axis in a bore-type system or towards the central plane in a gap-type system).

Alternatively, it is possible to increase the size of the bore (in a bore-type system) or the gap between pole faces (in a gap-type system) with minimal compromise on the efficiency of the gradient coil. This may be achieved by increasing the diameter of the bore (in a bore-type system) or by moving the pole faces farther apart (in a gap-type system), while moving a part of the gradient coil towards the central axis (in a bore-type system) or the central plane (in a gap-type system) as disclosed herein. Preferably, the part of the gradient coil that is moved closer to the central axis or central plane would be situated outside the examination region. In this way, a more efficient gradient coil can be realized without compromising patient comfort.

### BRIEF DESCRIPTION OF THE DRAWINGS

These and other aspects will be described in detail hereinafter by way of example on the basis of the following embodiments, with reference to the accompanying drawings, wherein:

FIG. 1a shows a first embodiment of the gradient coil according to the designs disclosed herein, including shielding coils;

FIG. 1b shows a second embodiment of the gradient coil according to the designs disclosed herein, without shielding coils;

FIG. 2 shows a third embodiment of the gradient coil according to the designs disclosed herein, wherein the flare at the mouth of a bore-type MR system is increased;

FIG. 3 shows a fourth embodiment of the gradient coil according to the designs disclosed herein, wherein a part of the radio-frequency (RF) coil overlaps with a part of the portion of the gradient coil that has been moved inwards, i.e., towards the central axis;

FIG. 4 shows a fifth embodiment of the gradient coil according to the designs disclosed herein, wherein a portion of the gradient coil is moved inwards only on one side of the examination region;

FIG. 5 shows a sixth embodiment of the gradient coil according to the designs disclosed herein, wherein the design is implemented in a gap-type MR system; and

FIG. 6 shows a magnetic resonance system including gradient coils according to the designs disclosed herein.

Corresponding reference numerals used in the various figures represent corresponding elements in the figures.

### DETAILED DESCRIPTION OF EMBODIMENTS

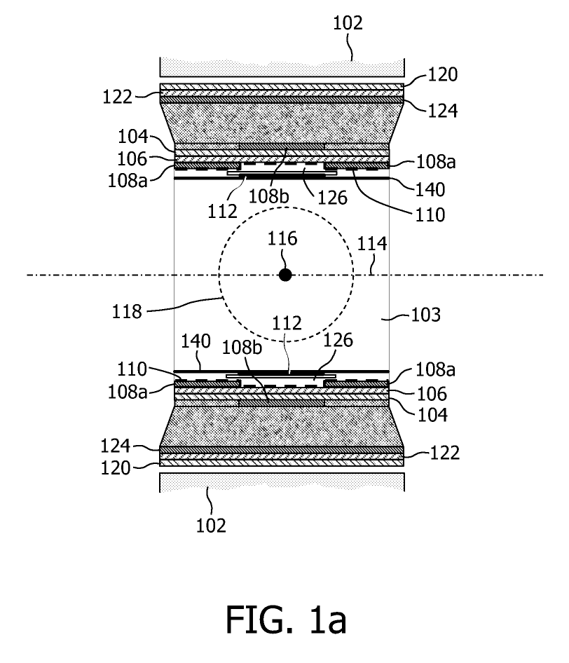

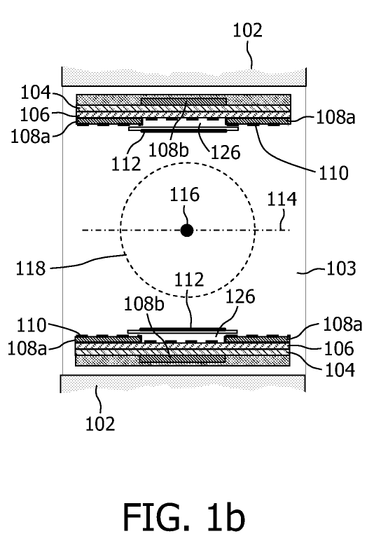

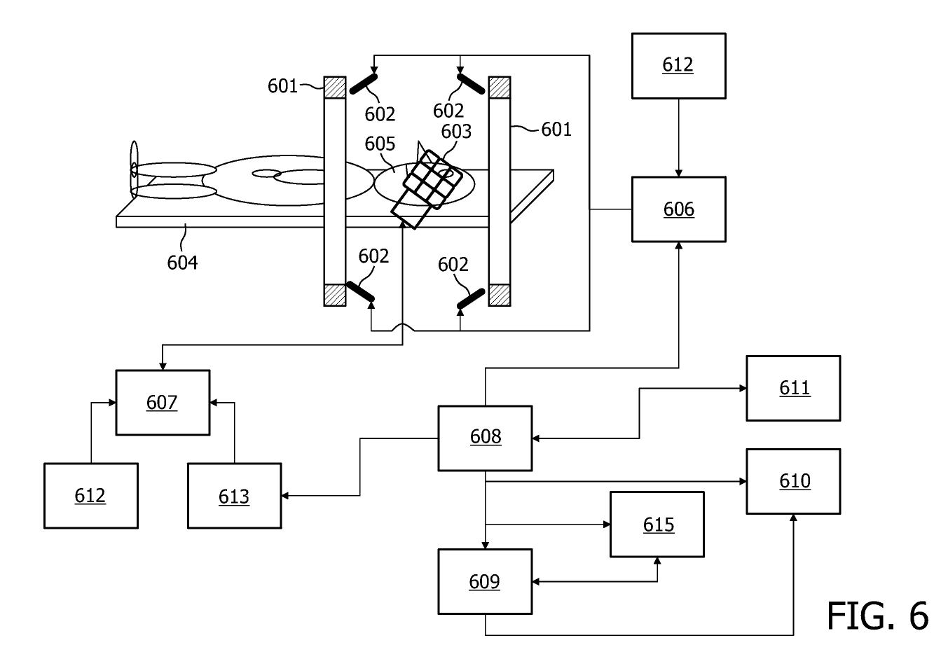

FIG. 1a shows a cylindrical magnet 102 (also referred to as a bore-type magnet) that houses a gradient coil system consisting of three gradient coils, specifically an x-axis gradient coil 104, a y-axis gradient coil 106 and a z-axis gradient coil 108a, 108b for producing magnetic field gradients along the x-axis, y-axis and z-axis of the cylindrical magnet, respectively. The gradient system also consists of three shielding coils, one each for the x, y and z-axis gradient coils. These shielding coils are show in FIG. 1a as an x-axis shielding coil 120, a y-axis shielding coil 122 and a z-axis shielding coil 124. The cylindrical magnet 102 includes a tunnel-like space or bore 103 comprising an examination region 118 that is arranged to receive a subject for examination, for example, a human patient (605 in FIG. 6). The line 114 denotes the main longitudinal axis of the cylindrical magnet, also called the central axis. In the current embodiment, the central axis coincides with the z-axis of the magnet and gradient systems. The dot 116 on the central axis 114 indicates the geometrical center of the bore 103, and is designated as the origin, or the zero-coordinate, of the central axis. The dot 116 also represents the geometric center of the examination region 118. The z-axis gradient coil is shown as consisting of two different portions, viz., a first portion 108a and a second portion 108b that are disposed at different distances from the central axis 114. Due to the difference in distances of the first portion 108a and the second portion 108b from the central axis, a recess 126 is formed in the gradient coil. An RF coil 112, positioned around the origin 116, is electrically shielded from the gradient coils using an RF screen 110. The RF screen 110 is typically attached to the gradient coil system. A patient cover 140 forms the innermost surface of the MR system forming the peripheral surface of the bore of the MR system.

FIG. 1b shows a setup similar to that in FIG. 1a, except that the x-axis gradient coil 104, y-axis gradient coil 106 and the z-axis gradient coil 108a, 108b are unshielded gradient coils, i.e., they do not have corresponding shielding coils.

In the embodiments shown in FIG. 1a and FIG. 1b, the second portion 108b of the z-axis gradient coil is shown as being the farthest away from the central axis 114. The other gradient coils, namely the y-axis gradient coil 106 and the x-axis gradient coil 104 are positioned closer to the central axis 114. The positions of the x-axis and y-axis gradient coils may be interchanged.

With continuing reference to FIG. 1a and FIG. 1b, the first portion 108a of the z-axis gradient coil is positioned nearer the central axis 114 in a radial direction compared to the second portion 108b. Though in the specific embodiment shown, the change in the diameter of the cross-section of the gradient coil happens abruptly, (i.e., in the form of a step or a series of steps), it is possible to have a more gradual change in cross-sectional diameter, for example, if the gradient coil were to be wound on a conical former. Practically, the difference in the distance of the first portion 108a and the second portion 108b from the central axis may be in the range of 1 cm, 1.5 cm or 2 cm. The invention will work with other values for the difference in the distance as well.

Compared to an MR system wherein the first portion 108a of the z-axis gradient coil is positioned at the same radial distance from the central axis 114 as the second portion 108b, the design proposed herein exhibits an improved performance of the z-axis gradient coil. The improvement depends on the thickness of the x-axis, y-axis and z-axis gradient coils and the distance from the z-axis gradient coil to the RF screen 110. In certain cases, the performance improvement in gradient coil efficiency achieved by adopting the designs disclosed herein may be in the order of 25-35%. Alternatively, in order to maintain the same level of performance of the z-axis gradient coil 108a, 108b it may be sufficient to use a lower-powered driver circuit (not shown) for the z-axis gradient coil, in which case a reduction in system cost is possible. Alternatively, in order to maintain the same level of performance of the z-axis gradient coil 108a, 108b, its diameter may be uniformly increased over the entire length of the z-axis gradient coil, which would result in a corresponding increase in the bore-diameter of about 1.5 cm or 2 cm, which could in turn, result in increased patient comfort.

Thus, the designs proposed herein enable extra space to be created in the center of a gradient coil without severely compromising the quality of the gradient coil—in particular, its efficiency—by changing the radial distance of the coil pattern from the central axis 114. The extra space so created may be used to incorporate additional features in the MR system. For example, in the case of a combined positron emission tomography (PET)-MR scanner, a circular PET detector array could be placed in the recess 126 in the gradient coil without adversely affecting the diameter of the bore. Alternatively, a ring-type X-ray detector could be placed in the recess 126 to give a combined computed tomography (CT)-MR scanner. Other detector devices to detect other forms of radiation may also be placed in the recess. As another example, additional shimming coils or field compensation coils that may be used to compensate for the field quality of the gradient coil (e.g., to get a more homogeneous gradient field) may be placed in the gradient coil, adjacent to and inside the second portion 108b, i.e., closer to the central axis 114.

It may be noted that though only the z-axis gradient coil 108a, 108b is shown to be split into two portions located at different distances from the central axis 114, the x-axis and/or the y-axis gradient coils 104, 106 may also be modified in a similar fashion. Furthermore, in other embodiments, more than one of the gradient coils may be similarly modified at the same time.

Furthermore, the two portions of a gradient coil as disclosed herein may be positioned on opposite sides of one or more of the other gradient coils. For example, in the embodiments shown in FIG. 1a and FIG. 1b, the z-axis gradient coil is shown with the first portion 108a of the z-axis gradient coil positioned inside (i.e., radially closer to the central axis 114) of the x-axis and y-axis gradient coils 104, 106, and the second portion 108b of the z-axis gradient coil positioned on the outside (i.e., radially father away from the central axis 114) of the x-axis and y-axis gradient coils 104, 106. In alternative embodiments, the first and second portions of the z-axis gradient coil 108a, 108b may be positioned on either side of only one of the other gradient coils, for instance, the x-axis gradient coil 104 or the y-axis gradient coil 106. Alternatively, it is also possible to position both the first and second portions of the z-axis gradient coil 108a, 108b on the same side of both the other gradient coils. For example, both the first and second portions of the z-axis gradient coil 108a, 108b could be positioned radially closer to the central axis 114 compared to the x-axis and y-axis gradient coils 104, 106, while still maintaining the difference in the cross-sectional diameter between the two portions 108a, 108b.

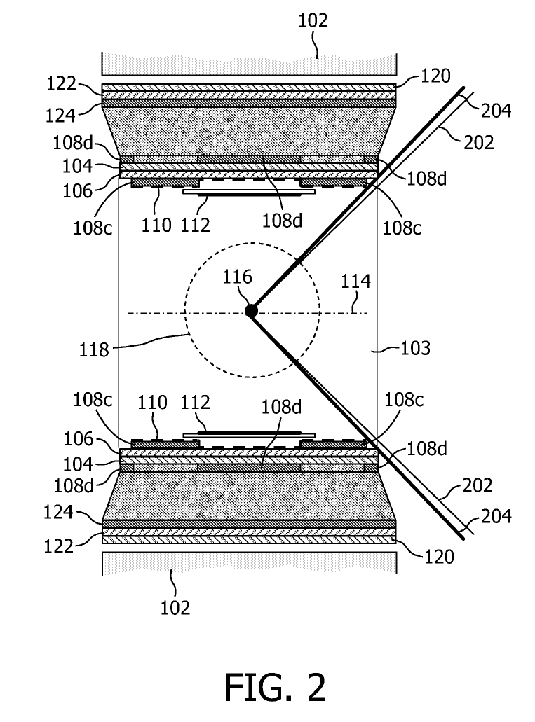

FIG. 2 shows an embodiment of the z-axis gradient coil disclosed herein implemented for an unshielded gradient coil system, wherein a first coil portion 108c of the z-axis gradient coil is moved radially inward towards the central axis 114, compared to a second coil portion 108d of the z-axis gradient coil.

The first coil portion 108c of the z-axis gradient coil is so selected that only that part of the z-axis gradient coil that extends beyond the ends of the RF coil 112, is positioned closer to the central axis 114. Additionally, in this particular embodiment, the first portion 108c does not extend all the way to the ends of the bore or the tunnel-like space 103; rather, the first portion 108c stops short of the ends of the bore 103 by a specific amount, e.g., 10 cm or 20 cm. The advantage of such a design is that the “flare” at the ends of the bore 103 can be maintained or even increased, which further improves patient comfort. The flare of the bore 103 may be defined by a line connecting the origin 116 to the periphery of the bore 103 at the ends of the bore 103. This is shown in FIG. 2 by the pairs of lines 202 and 204. Lines 202 indicate the flare of the bore 103 if the first portion 108c of the z-axis gradient coil were to be extended all the way to the ends of the bore 103, while the lines 204 show the flare when the first portion 108c of the z-axis gradient coil stops short of the ends of the bore 103 by a specific amount, as discussed above.

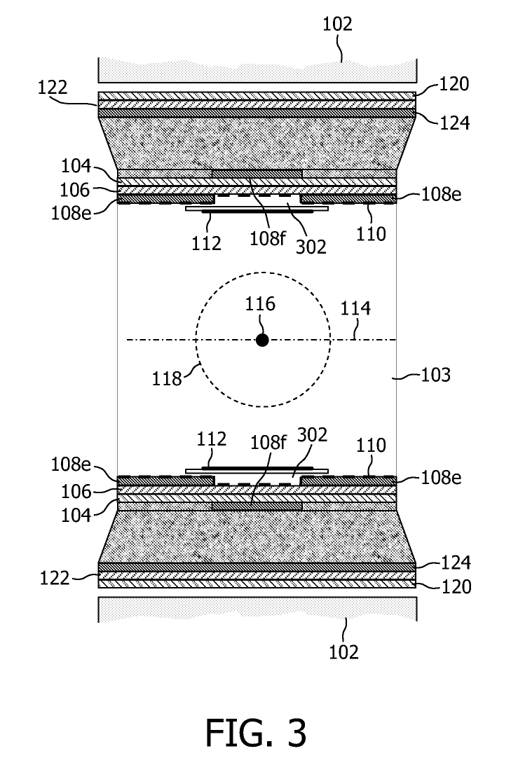

FIG. 3 shows a possible embodiment of the gradient coil design disclosed herein, in which the portion of the z-axis gradient coil that has been moved radially towards the central axis 114 extends beyond the ends of the RF coil 112. Specifically, the first portion 108e of the z-axis gradient coil is shown as having been moved radially inward and extending beyond the ends of the RF coil 112, while the second portion 108f of the z-axis gradient coil is shown in its original place.

It may be noted that, in the particular embodiments shown in FIGS. 1a, 1b and 2, the z-axis gradient coil is moved closer to the central axis 114 only in those regions of the z-axis gradient coil that fall outside the ends of the RF coil 112, i.e., there is no overlap shown between the first portion 108a, 108c of the z-axis gradient coil and the RF coil 112. However, as shown in FIG. 3, it is indeed possible to have such an overlap of the first portion 108e of the z-axis gradient coil with the RF coil (for example, the rings of a birdcage-type RF coil, or with the ends of a planar loop coil). In other words, as the RF screen 110 is attached to the gradient coil, an overlap of the RF screen 110 and the RF coil 112 is indeed allowed, and might even help to reduce the specific absorption rate (SAR) from the RF coil 112. However, such an overlap has a negative effect on the performance of the RF coil 112, and therefore, it may be preferable not to have much of an overlap between the RF coil 112 and the first portion 108e of the z-axis gradient coil.

Referring to FIGS. 1a, 1b and 2, a typical RF coil, for example a “body coil” that is often of a birdcage design in a typical MR system, has a length of about 50 cm, and is positioned with its geometric center at the origin 116; therefore, the z-axis gradient coil is positioned at a smaller radius only for the region beyond about 25 cm on either side from the origin 116 (in FIGS. 1a, 1b and 2). The x-axis and y-axis gradient coils 104, 106 remain at their original diameter in these embodiments.

Referring back to FIG. 3, if the length of the cylindrical magnet 102 is decreased, the length of the bore 103 along the central axis 114 will also decrease correspondingly. This could result in the two sections of the first portion 108e of the z-axis gradient coil (i.e., on two sides of the second portion 108f) coming closer together, thereby reducing the recess or gap 302 between them. If the recess 302 becomes shorter than the length of the RF coil 112, it could result in a longer portion of the z-axis gradient coil being on the smaller radius. In other words, the first portion 108e of the z-axis gradient coil would be longer along the central axis 114 than the second portion 108f of the z-axis gradient coil, which would improve the performance of the z-axis gradient coil. However, due to the recess 302 being smaller, part of the first portion 108e of the z-axis gradient coil would overlap with the ends of the RF body coil 112, e.g., the part closer to the end-rings of a birdcage RF coil. It may be noted that reducing the size of the recess 302 results in a slight reduction of B, homogeneity in the examination region 118, which may introduce a higher chance of back-folding or aliasing artifacts appearing in the final image.

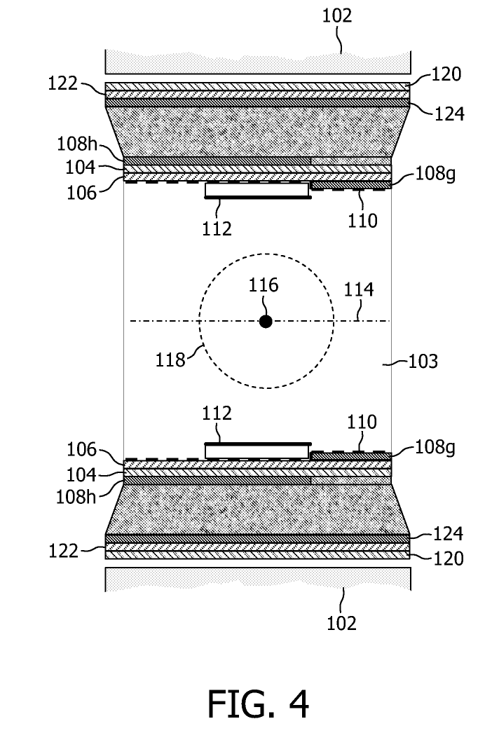

FIG. 4 shows an embodiment of the gradient coil disclosed herein, in which the first portion 108g of the z-axis gradient coil is asymmetric with respect to the origin 116 along the central axis 114. The second portion 108h of the z-axis gradient coil extends from one end of the bore 103 to the point where first portion 108g of the gradient coil begins, though at a different radial distance from the central axis 114.

In case the RF coil 112, e.g. a head coil, is slid into the bore 103 prior to imaging, then this particular embodiment of the gradient coil design has the advantage of being able to accept larger RF coils 112 compared to some other embodiments. Also, the flare at the two ends of the bore can be different, which might be advantageous in some instances. For example, if a subject (for instance, a human patient 605 as shown in FIG. 6) is slid into the bore 103 from the end having the second portion 108h of the gradient coil, then the larger flare at that particular end of the bore 103 may help reduce patient discomfort.

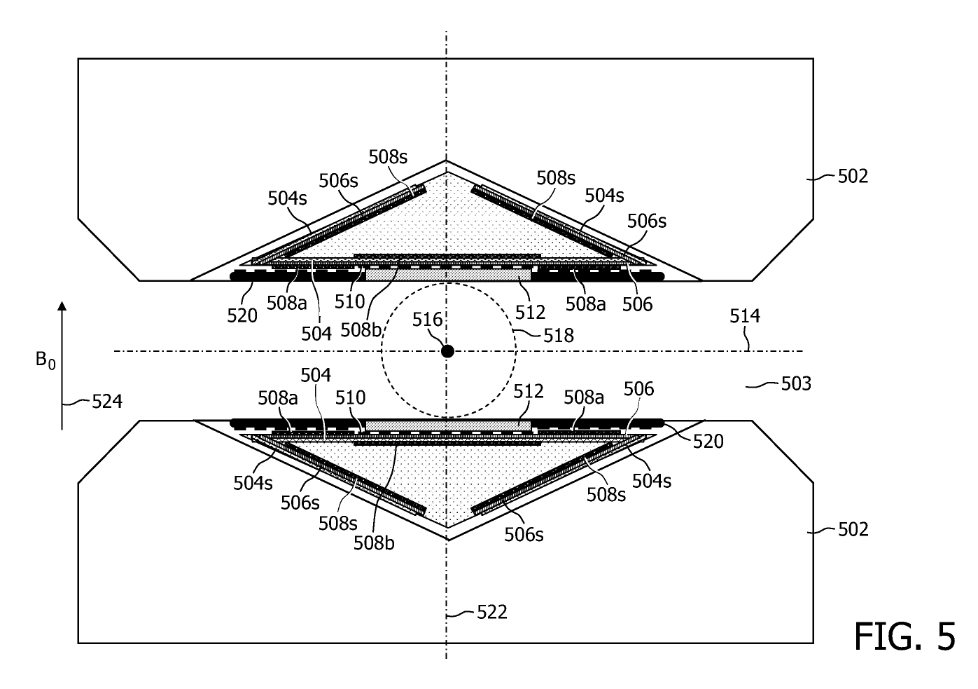

FIG. 5 shows an embodiment of the gradient coil design disclosed herein, as implemented in a gap-type or open magnet system. Two pole pieces 502 of the open magnet are separated by a gap 503. A gradient coil, physically split into two halves but electrically connected to form one coil, is mounted on the pole pieces, with each half being mounted on a different pole piece. This pattern is repeated for all the three gradient coils. In the specific embodiment shown, the y-axis gradient coil 506 is shown sandwiched between the x-axis gradient coil 504 on one side and a first portion 508a of the z-axis gradient coil on the other. The second portion 508b of the z-axis gradient coil is mounted on the pole piece 502 on the side of the x-axis gradient coil 504 that is opposite to the y-axis gradient coil 506. The conical or side portion of the z-axis gradient coil 508s is a z-axis shielding coil. Similarly, the side portions of the x-axis gradient coil 504s and the side portions of the y-axis gradient coil 506s form the x-axis and y-axis shielding coils, respectively. The line 522 denotes the main axis of the magnetic pole pieces and also represents the axis along which the main magnetic field is applied, commonly called the z-axis of the MR system. The direction of the main magnetic field B₀ in this particular embodiment is denoted by the arrow 524. The line 514 denotes a plane that is perpendicular to the direction of the main magnetic field B₀, i.e., a plane to which the main axis 522 of the magnetic pole pieces forms a normal. This plane is designated as the central plane 514. The dot 516 indicates the geometrical center of the gap 503, and is designated as the origin, or the zero-coordinate, of the central plane. The dot 516 also represents the geometric center of the examination region 518 that is comprised in the gap 503. The examination region 518 is configured to receive a subject for examination (605 in FIG. 6) in a plane parallel to the central plane 514. The z-axis gradient coil is shown as consisting of a first portion 508a and a second portion 508b that are disposed at different distances from the central plane 514. An RF coil 512, positioned around the origin 516 of the central plane 514, is electrically shielded from the gradient coils using an RF screen 510. A patient cover 520 protects the subject from direct contact with the RF and gradient coils.

As shown in FIG. 5, open or gap-type MR systems generally have two halves of a gradient coil mounted on two opposing pole pieces to generate the desired magnetic field gradients. The distance between the pole pieces determines the space available to accommodate a subject, for example a human or animal patient. Therefore, to maximize patient comfort, a large gap between the pole pieces is desirable, which leads to a large separation between the two halves of the gradient coil. A large distance between the gradient coil halves increases the stored field energy, which in turn reduces the efficiency of the gradient coil. A low efficiency for the gradient coil requires more power from a gradient amplifier leading to higher operating costs. Hence, it is desirable to minimize the distance between the two halves of a gradient coil.

Additionally, as shown in the FIG. 5, the first portion 508a of the z-axis gradient coil has a larger diameter compared to the second portion 508b, and therefore contributes more to the stored field energy. As explained earlier, one way of reducing the stored field energy is to reduce the distance between the upper and lower halves of the gradient coil. Thus, the z-axis gradient coil portion with a larger diameter (in this case, the first portion 508a) can be placed at a smaller z-position, i.e. closer to the central plane 514. Typically, this space is unused in an open-MR system, and therefore can be used very efficiently to house the first portion 508a of the z-axis gradient coil. As the distance of the first coil portion 508a to the central plane 514 is reduced, the required gradient fields for imaging can be generated more efficiently in the examination region. Furthermore, as the distance between the first coil portion 508a and the z-axis shielding coil 508s is increased, fewer windings are required in the shielding coil 508s, which makes the z-axis gradient coil even more efficient in operation.

By using hollow conductors in the construction of the z-axis gradient coil and circulating cooling fluid though it, a directly-cooled z-axis gradient coil is obtained. The cooling fluid may be water or liquid nitrogen or other liquid coolant. Alternatively, the cooling fluid may be air or other coolant in a gaseous form. Alternatively, the cooling fluid may be a combination of multiple liquids or multiple gases or both. By a “direct cooled” z-axis gradient coil, it is meant that the heat generated by the z-axis gradient coil is removed by the cooling fluid circulating in the hollow coil itself. In contrast, the heat generated by other gradient coils (for example, the x-axis and y-axis gradient coils) that do not have a circulating cooling fluid has to be removed by first transferring it to the directly-cooled z-axis gradient coil. In case of a z-axis gradient coil as shown in the various figures, if other gradient coils are sandwiched between two layers of z-axis gradient coil 508a, 508b, efficient cooling of the other gradient coils could be attained as well. Furthermore, due to the proximity of the patient cover 520 to the second portion 508b of the z-axis gradient coil, the patient covers remain cool as well, thereby further enhancing patient comfort.

It may be noted that though the gradient coils are shown to be split into two equal halves, it is possible to have asymmetric designs as well. For example, it is conceivable that a larger part of the gradient coil winding is mounted on one side of the examination region compared to the gradient coil winding on the other side. It is also possible to implement the disclosed gradient coil designs in a gradient coil that is mounted only on one side of the examination region. It is also conceivable that instead of two portions for the z-axis gradient coil 108a, 108b or 508a, 508b, the gradient coil could be split into additional portions. It is possible to implement the design in shielded gradient or unshielded gradient coils, disc-type gradient coils, etc. The proposed design of the gradient coil may be applied to any of the gradient coils, namely, x, y or z-axis gradient coils, or to any combination thereof.

FIG. 6 shows a possible embodiment of an MR system utilizing the gradient coil designs disclosed herein. The MR system comprises a set of main coils 601, multiple gradient coils 602 connected to a gradient driver unit 606, and RF coils 603 connected to an RF coil driver unit 607. The function of the RF coils 603, which may be integrated into the magnet in the form of a body coil, and/or may be separate coils, might further be controlled by one or more transmit/receive (T/R) switches 613. The multiple gradient coils 602 and the RF coils 603 are powered by a power supply unit 612. A transport system 604, for example a patient table, is used to position a subject 605, for example a patient, within the MR imaging system. A control unit 608 controls the RF coils 603 and the gradient coils 602. The control unit 608 further controls the operation of a reconstruction unit 609. The control unit 608 also controls a display unit 610, for example a monitor screen or a projector, a data storage unit 615, and a user input interface unit 611, for example, a keyboard, a mouse, a trackball, etc.

The main coils 601 generate a steady and uniform static magnetic field, for example, of field strength 1.0 T, 1.5 T or 3 T. The disclosed methods are applicable to other field strengths as well. The main coils 601 are arranged in such a way that they typically enclose a tunnel-shaped examination space (also called the bore of the system), into which the subject 605 may be introduced. Another common configuration comprises opposing pole faces with an air gap in between them into which the subject 605 may be introduced by using the transport system 604. To enable MR imaging, temporally variable magnetic field gradients superimposed on the static magnetic field are generated by the multiple gradient coils 602 in response to currents supplied by the gradient driver unit 606. The multiple gradient coils 602 consist of x, y and z-axis gradient coils capable of generating magnetic field gradients in the x, y and z-axis, respectively, of the MR system. One or more of the x, y and z-axis gradient coils may adopt the gradient coil designs as disclosed herein. The power supply unit 612, fitted with electronic gradient amplification circuits, supplies currents to the multiple gradient coils 602, as a result of which gradient pulses (also called gradient pulse waveforms) are generated. The control unit 608 controls the characteristics of the currents, notably their strengths, durations and directions, flowing through the gradient coils to create the appropriate gradient waveforms. The RF coils 603 generate RF excitation pulses in the subject 605 and receive MR signals generated by the subject 605 in response to the RF excitation pulses. The RF coil driver unit 607 supplies current to the RF coil 603 to transmit the RF excitation pulses, and amplifies the MR signals received by the RF coil 603. The transmitting and receiving functions of the RF coil 603 or set of RF coils are controlled by the control unit 608 via the T/R switch 613. The T/R switch 613 is provided with electronic circuitry that switches the RF coil 603 between transmit and receive modes, and protects the RF coil 603 and other associated electronic circuitry against breakthrough or other overloads, etc. The characteristics of the transmitted RF excitation pulses, notably their strength and duration, are controlled by the control unit 608.

It is to be noted that though the transmitting and receiving coil is shown as one unit in this embodiment, it is also possible to have separate coils for transmission and reception, respectively. It is further possible to have multiple RF coils 603 for transmitting or receiving or both. The RF coils 603 may be integrated into the magnet in the form of a body coil, or may be separate surface coils. They may have different geometries, for example, a birdcage configuration or a simple loop configuration, etc.

The control unit 608 is preferably in the form of a computer that includes a processor, for example a microprocessor. The control unit 608 controls, via the T/R switch 613, the application of RF pulse excitations and the reception of MR signals comprising echoes, free induction decays, etc. User input interface devices 611 like a keyboard, mouse, touch-sensitive screen, trackball, etc., enable an operator to interact with the MR system. The MR signal received with the RF coils 603 contains the actual information concerning the local spin densities in a region of interest of the subject 605 being imaged. The received signals are reconstructed by the reconstruction unit 609, and displayed on the display unit 610 as an MR image or an MR spectrum. It is alternatively possible to store the signal from the reconstruction unit 609 in a storage unit 615, while waiting for further processing. The reconstruction unit 609 is constructed advantageously as a digital image-processing unit that is programmed to derive the MR signals received from the RF coils 603.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the system claims enumerating several means, several of these means can be embodied by one and the same item of computer readable software or hardware. The mere fact that certain measures are recited in mutually different dependent claims does not indicate that a combination of these measures cannot be used to advantage.

1. A magnetic resonance system comprising:
a main magnet, including a bore, arranged to generate a main magnetic field along the bore;
an examination region comprised in the bore and having a central axis parallel to the direction of the main magnetic field; and
a primary gradient coil for generating a magnetic field gradient across the examination region, wherein the primary gradient coil comprises a first coil portion and a second coil portion located at different distances from the central axis.

2. A magnetic resonance system comprising:
a main magnet, including multiple pole pieces separated by a gap, arranged to generate a main magnetic field in the gap;
an examination region comprised in the gap and having a central plane perpendicular to the direction of the main magnetic field; and
a primary gradient coil for generating a magnetic gradient field across the examination region, wherein the primary gradient coil comprises a first coil portion and a second coil portion located at different distances from the central plane.

3. The magnetic resonance system of claim 1, wherein the difference in the distances of the first coil portion and the second coil portion from the central axis forms a recess, and wherein a radio-frequency coil is located in the recess.

4. The magnetic resonance system of claim 2, wherein the difference in the distances of the first coil portion and the second coil portion from the central plane forms a recess, and wherein a radio-frequency coil is located in the recess.

5. The magnetic resonance system of claim 1, wherein the difference in the distances of the first coil portion and the second coil portion from the central axis forms a recess, and wherein a detector device configured to detect electromagnetic radiation is located in the recess.

6. The magnetic resonance system of claim 2, wherein the difference in the distances of the first coil portion and the second coil portion from the central plane forms a recess, and wherein a detector device configured to detect electromagnetic radiation is located in the recess.

7. The magnetic resonance system of claim 1, including one or more additional gradient coils, wherein the first coil portion and the second coil portion of the primary gradient coil are disposed on opposite sides of at least one of the additional gradient coils.

8. The magnetic resonance system of claim 1, wherein the first coil portion and/or the second coil portion are made of a hollow conducting material configured to carry a cooling fluid.

9. The magnetic resonance system of claim 8, including a cover adjacent the examination region, wherein the first coil portion and/or the second coil portion is further arranged to cool the cover in the proximity of at least the examination region.

10. The magnetic resonance system of claim 1, wherein the first coil portion and the second coil portion of the primary gradient coil are arranged to maximize a flare of the bore of the magnetic resonance system.
